(19) United States
(12) Patent Application Publication
(10) Pub. No.: US 2008/0049398 A1
(43) Pub. Date: Feb. 28, 2008

(54) APPARATUS, SYSTEM, AND METHOD FOR MODIFYING A THERMAL CONNECTION

(76) Inventors: Vaughn A. Griffiths, North Logan, UT (US); Michael S. Watson, North Logan, UT (US)

Correspondence Address: Kunzler & McKenzie, 8 EAST BROADWAY, SUITE 600, SALT LAKE CITY, UT, 84111, US

(21) Appl. No.: 11/467,431

(22) Filed: Aug. 25, 2006

(51) Int. Cl. H05K 7/20

(52) U.S. Cl. 361/704

(57) ABSTRACT

An apparatus, system, and method are disclosed for modifying thermal connections. An actuator motivates a thermal connector. In one embodiment, the actuator is configured as a wax actuator that motivates the thermal connector in response to melted wax. The thermal connector contacts a first body to form a thermal connection between the thermal connector the first body. A thermal link conducts heat through the thermal connection. In one embodiment, the thermal link conducts heat between the first body and a second body. In addition, the actuator may separate the thermal connector from the first body and stop the transport of heat.

### BACKGROUND OF THE INVENTION

1. Field of the Invention

This invention relates to thermal connections and more particularly relates to modifying a thermal connection.

2. Description of the Related Art

Thermal connections are often employed to transport heat from a heat load to a cold source. Transporting the heat cools the heat load and may maintain the temperature of the heat load within a specified range. For example, instrumentation of a space vehicle may employ a thermal connection to transport heat from the instrumentation to a cold source to maintain the instrumentation temperature within a specified operating range. Alternatively, a thermal connection may transport heat to a cold load to maintain the temperature of the cold load within a specified range.

The amount of heat that must be transported over the thermal connection may vary. Continuing the example above, the instrumentation of the space vehicle may require that significantly more heat be transported while the space vehicle is exposed to sunlight than when the space vehicle is protected from sunlight by a shadow. Similarly, the instrumentation may require that more heat be transported when the instrumentation is operating than when the instrumentation is idle.

Unfortunately, many of the environments that require thermal connections to cool heat loads or heat cold loads may make modifying typical mechanical connections impractical. For example, the environment may limit the available power, impose harsh operating conditions, and/or require that environmental cleanliness be strictly maintained. In the example above, the space vehicle may have a restricted power budget, and may require that mechanical devices operate in a vacuum with minimal out-gassing and/or related production of contaminants.

From the foregoing discussion, it should be apparent that a need exists for an apparatus, system, and method that modify a thermal connection. Beneficially, such an apparatus, system, and method would support a variable thermal transport.

### SUMMARY OF THE INVENTION

The present invention has been developed in response to the present state of the art, and in particular, in response to the problems and needs in the art that have not yet been fully solved by currently available thermal connection modification methods. Accordingly, the present invention has been developed to provide an apparatus, system, and method for modifying a thermal connection that overcome many or all of the above-discussed shortcomings in the art.

The apparatus to modify a thermal connection is provided with a plurality of elements configured to functionally execute the steps of motivating a thermal connector, contacting the thermal connector to a first body, and conducting heat through a thermal link. These elements in the described embodiments include a thermal connector, a thermal link, and an actuator.

The thermal connector is configured to contact the first body to form a thermal connection. In one embodiment, the first body is a heat load. Alternatively, the first body may be cold load. The thermal connector may comprise a highly conductive material such as copper, aluminum, or the like. In a certain embodiment, the thermal connector contacts the heat load over a contact surface that maximizes the heat transfer between the thermal connector and the heat load.

The thermal link is in thermal communication with the thermal connector. In addition, the thermal link is configured to transport heat. In one embodiment, the thermal link is a passive heat conductor that conducts heat between the thermal connector and a second body. In an alternate embodiment, the thermal link includes an active heat transport device. The thermal link may be configured as a flexible member.

The actuator motivates the thermal connector to contact the first body. In one embodiment, the actuator is a wax actuator. The actuator may latch with the thermal connector in contact with the first body. In addition, the actuator may unlatch and motivate the thermal connector to separate from the first body. The apparatus modifies the thermal connection by motivating the thermal connector to contact with and separate from the first body, modifying the thermal transport through the thermal connector and thermal link.

A system of the present invention is also presented to modify a thermal connection. The system may be embodied in a cooling system. In particular, the system, in one embodiment, includes a cold source, and heat load, and a thermal transport. The thermal transport may include a thermal connector, a thermal link, and a wax actuator.

The heat load may be required to remain within a specified operational temperature range. In addition, the heat load may generate heat and/or receive ambient and/or radiated heat. The thermal connector is configured to contact the heat load to form a thermal connection. The thermal link is in communication with the thermal connector and the cold source.

The wax actuator motivates the thermal connector to contact the heat load, form the thermal connection, and allow heat to flow from the heat load through the thermal connector and thermal link to the cold source. In additional, the wax actuator may motivate the thermal connector to separate from the heat load to stop the thermal transport from the heat load.

In one embodiment, the heat load is disposed on a space vehicle. The heat load may comprise instrumentation that must operate within a specified temperature range. The thermal transport may be configured to operate in a high vacuum environment. In additional, the thermal transport may be configured to modify the thermal transport with reduced power consumption. By motivating the thermal connector to contact with and separate from the heat load, wax actuator modifies the thermal connection between the heat load and cold source and regulates the heat transport through the thermal link.

A method of the present invention is also presented for modifying a thermal connection. The method in the disclosed embodiments substantially includes the steps to carry out the functions presented above with respect to the operation of the described apparatus and system. In one embodiment, the method includes motivating a thermal connector, contacting the thermal connector to a first body, and conducting heat through a thermal link.

An actuator motivates a thermal connector. In one embodiment, the actuator is configured as a wax actuator that motivates the thermal connector in response to melted wax. The thermal connector contacts a first body to form a thermal connection between the thermal connector the first body. A thermal link conducts heat through the thermal connection. In one embodiment, the thermal link conducts heat between the first body and a second body. In addition, the actuator may separate the thermal connector from the first body and stop the transport of heat. The method modifies the thermal connection by contacting and separating the thermal connector with the first body.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

The embodiment of the present invention modifies a thermal connection. In addition, the embodiment of the present invention may modify the transport of heat to maintain a specified temperature range and/or rate of heat transport. These features and advantages of the present invention will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a perspective drawing illustrating one embodiment of a thermal transport system of the present invention;

FIG. 2 is a schematic block diagram illustrating one embodiment of a thermal connection modifying apparatus of the present invention;

FIG. 3 is a perspective drawing illustrating one embodiment of a wax actuator of the present invention;

FIG. 4 is a perspective drawing illustrating one embodiment of an actuator control system of the present invention;

FIG. 5 is a perspective drawing illustrating one embodiment of a cryogen-based thermal transport system of the present invention;

FIG. 6 is a perspective drawing illustrating one alternate embodiment of a cryogen-based thermal transport system of the present invention;

FIG. 7 is a perspective drawing illustrating one embodiment of a zero contact force thermal transport system of the present invention;

FIG. 8 is a schematic flow chart diagram illustrating one embodiment of a thermal connector contact method of the present invention; and

FIG. 9 is a schematic flow chart diagram illustrating one embodiment of a thermal connector separation method of the present invention.

### DETAILED DESCRIPTION OF THE INVENTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

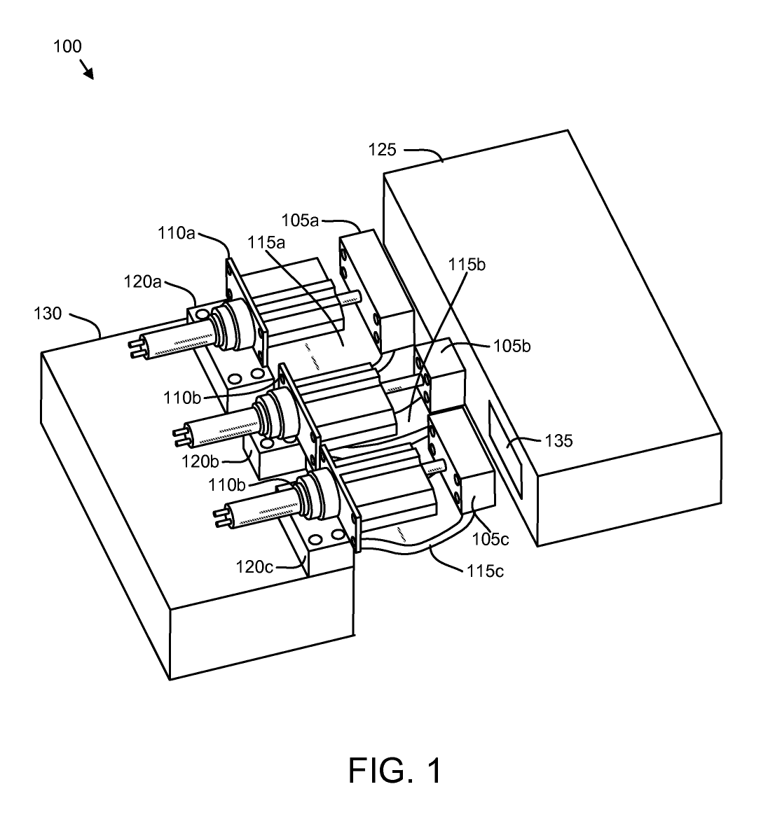

FIG. 1 is a perspective drawing illustrating one embodiment of a thermal transport system 100 of the present invention. The system 100 includes one or more thermal connectors 105, one or more actuators 110, one or more thermal links 115, one or more actuator mounts 120, a first body 125, and a second body 130. In particular, the system 100 is depicted with three thermal connectors 105, actuators 110, and thermal links 115 for illustrative purposes. However, the system 100 may employ any number of thermal connectors 105, actuators 110, and thermal links 115, as well as any number of first bodies 125 and second bodies 130.

The terms first body 125 and second body 130 are employed to differentiate between sources of heat and sinks for transported heat. For example, the first body 125 may be a heat load while the second body may be a cold source. In an alternate prophetic example, the first body 125 may be a cold load and the second body 130 may be a heat source.

The thermal connector 105 is configured to contact the first body 125 to form a thermal connection. In the depicted prophetic example, a second thermal connector 105b contacts the first body 125 while a first and third thermal connector 105a, 105c are separated from the first body 125.

In a certain embodiment, the thermal connector 105 contacts the first body 125 at a contact surface such as the contact surface 135 shown for the third thermal connector 105c. An additional contact surface (not shown) may also be disposed on the third thermal connector 105c such that the contact surface of the third thermal connector 105c and the contact surface 135 of the first body 125 form a thermal connection.

The contact surface 135 may improve the heat transfer between the third thermal connector 105c and the first body 125. In one embodiment, the contact area 135 may be a polished metal surface. Alternatively, the contact area 135 may comprise interlocking protrusions. In one embodiment, a viscous thermal conductor is applied between the contact surface of the thermal connection 105 and the contact surface of the first body 125 to improve heat transfer.

The thermal link 115 is in thermal communication with the thermal connector 105. In addition, the thermal link 115 is configured to transport heat. The thermal link 115 may be configured as a flexible member. In the depicted system 100, a first and third thermal links 105a, 105c are depicted as flexed into a significant arc while the second thermal link 105b is flexed into a slight arc. The thermal link 115 may flex to maintain the thermal connection with the thermal connector 105 when the thermal connector 115 contacts the first body 125 and when the thermal connector 105 is separated from the first body 125.

In the depicted prophetic example, each thermal connector 105 has a unique surface area that is configured to contact the first body 125. In addition, each thermal connector 105/thermal link 115 pair may be configured to transport heat at a unique rate. Thus the rate of heat transport may be varied by the selection of thermal connectors 105 that contact the first body 125.

The actuator 110 motivates the thermal connector 105 to contact the first body 125. Each actuator 110 is shown mounted to the second body 130 using a corresponding actuator mount 120. Alternatively, each actuator 110 may be positioned within the system 100 using one or more fasteners, mounting fixtures, braces, struts, and the like as is well known to those skilled in the art.

Each actuator 110 may be connected to a controller as will be described hereafter. For simplicity the connection to the controller is not shown. The actuator 110 motivates thermal connector 105 under the control of the controller. In the depicted embodiment, the system 100 transfers heat between the first body 125 and second body 130 through the second thermal connector 105b and the second thermal link 110b. In a prophetic example, the system 100 may increase heat transfer by motivating one or more additional thermal connectors 105 such as the first and third thermal connectors 105a, 105c to contact the first body 125. The system 100 modifies the heat transfer by motivating the thermal connectors 105 to contact with and separate from the first body 125.

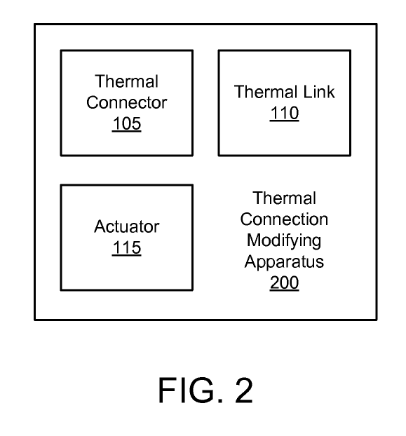

FIG. 2 is a schematic block diagram illustrating one embodiment of a thermal connection modifying apparatus 200 of the present invention. The apparatus 200 may be embodied by the thermal connector 105, thermal link 115, and actuator 110 of FIG. 1. In addition, the description of the apparatus 200 refers to elements of FIG. 1, like numbers referring to like elements.

The thermal connector 105 is configured to contact the first body 125 to form a thermal connection and to separate from the first body 125 to break the thermal connection. The thermal link 115 is in thermal communication with the thermal connector 105. In one embodiment, the thermal link 115 is in thermal communication through a solderless thermal link connection produced by Space Dynamics Laboratory of North Logan, Utah. The thermal link 115 may be held in physical communication with the thermal connector 105 by a fastener. Alternatively, the thermal link 115 may be adhesively bonded to the thermal connector 105. In a certain embodiment, the thermal link 115 is soldered to the thermal connector 105. The thermal link 115 may also be pressed in physical communication with the thermal connector 105 to create the thermal communication.

In one embodiment, the area of physical communication between the thermal link 115 and the thermal connector 105 is the range of between ten percent to ninety-five percent (10% -95%) of the surface area of the thermal connector 105. In a certain embodiment, the thermal link 115 is in physical communication with a conducting slug and the slug is physically connected to the thermal connector 105.

In one embodiment, the thermal link 115 is in thermal communication with the second body 130. The thermal link 115 may be held by a fastener, adhesively bonded, soldered, and/or pressed into thermal communication with the second body 130.

The thermal link 115 is configured to transport heat. In one embodiment, the thermal link 115 is a passive heat conductor that conducts heat between the thermal connector 105 and the second body 130. In an alternate embodiment, the thermal link 115 includes an active heat transport device such as a cryogen line, a heat pump line, or the like. A cryogen-based thermal link 115 will be described hereafter.

In one embodiment, the thermal link 115 is configured as a plurality of foil conductive layers. The conductive layers may comprise copper, aluminum, or the like. For example, the thermal link 115 may comprise a plurality of aluminum foil ribbon layers pressed at the ends of the ribbons into aluminum end blocks. In an alternative embodiment, the thermal link 115 is configured as a conductive braid such as a braid of copper wires, aluminum wires, or the like.

In one embodiment, the second body 130 is configured as a cold source. The second body 130 may be configured to radiate heat. In a certain embodiment, the second body 130 is configured to conduct heat to and/or from a third body such as a fuselage. Alternatively, the second body 130 may be cooled by a heat pump, a cryogen, or the like.

The actuator 110 motivates the thermal connector 105 to contact the first body 125. The actuator 110 may apply a force in response to heat. In one embodiment, the actuator 110 is a wax actuator as will be described hereafter. Alternatively, the actuator 110 may comprise a structural member that changes shape when heated. The structural member may exert a force as the structural member changes shape in response to the heat. In a prophetic example, the actuator 110 may comprise curved structural member that straightens in response to heat. Heating the structural member generates a force as the structural member straightens.

The actuator 110 may motivate the thermal connector 105 to contact to the first body 125 by applying a force in the range of zero point four newtons (0.4 N) to two thousand five hundred newtons (2,500 N) to the thermal connector 115, with the force directed toward the first body 125.

The actuator 110 may latch with the thermal connector 105 in contact with the first body 125. For example, a second actuator 110b may latch the second thermal connector 105b in contact with the first body 125 as shown in FIG. 1. The latched actuator 110 may consume no power. In addition, the actuator 110 may unlatch and motivate the thermal connector 105 to separate from the first body 125. The actuator 110 may also latch the thermal connector 105 as separated from the first body 125.

The apparatus 200 allows one or more thermal connectors 105 to be positioned in contact with the first body 125. In addition, one or more thermal connectors 105 may be separated from the first body 125. The apparatus 200 may vary the heat that is transported to and/or from the first body 125 by varying the number and selection of thermal connectors 105 that are positioned in contact with the first body 125. Thus the system 100 may transfer minimal heat through the thermal connectors 105 when each thermal connector 105 is separated from the first body 125 while the system may transfer maximum heat when each thermal connector 105 is in contact with the first body 125.

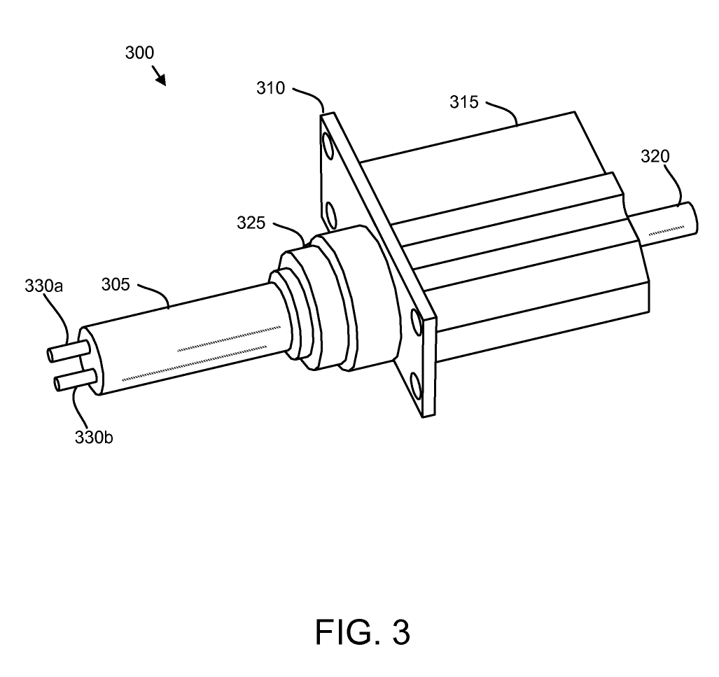

FIG. 3 is a perspective drawing illustrating one embodiment of a wax actuator 300 of the present invention. The wax actuator 300 includes a cable 305 with one or more wires 330, a base 325, a mounting plate 310, a body 315, and a plunger 320. The description of the wax actuator 300 refers to elements of FIGS. 1-2, like numbers referring to like elements. In one embodiment, the wax actuator 300 is a PP-5501 H.O.P. actuator from Starsys, Inc. of Boulder, Colo.

The wires 330 may form an electric circuit that carries electric current between the wax actuator 300 and a controller. The wires 330 may carry the electric current to a heating element disposed in the base 325. Alternatively, the wires 330 may carry the electric current to a heating element disposed in the body 315. The heating element is in communication with a reservoir of a thermal expansive substance such as wax that expands when heated. The actuator 300 is referred to as a wax actuator 300, although alternative thermal expansive substances may be employed.

When the electric current flows through the heating element, the heating element may emit heat that heats the thermal expansive substance. The heated thermal expansive substance may expand, pushing against a piston (not shown) disposed within the body 315. The piston may be physically connected to the plunger 320. The heated thermal expansive substance may push against the piston, motivating the plunger 320.

The piston may motivate the plunger 320 to an extended position wherein the tip of the plunger 320 is a maximum distance from the body 315. In an alternate embodiment, the piston may motivate the plunger 320 to a retracted position wherein the tip of the plunger 320 is a minimum distance from the body 315. In one embodiment, the heated thermal expansive substance motivating the piston moves the plunger from the retracted position to the extended position over a time interval in the range of fifteen to two hundred seconds (15-200 s). Similarly, the heated thermal expansive substance motivating the piston may move the plunger from the extended position to a retracted position over a time interval in the range of one to two hundred seconds (1-200 s).

The wax actuator 300 may be configured to operate in a reduced pressure environment. In one embodiment, the wax actuator 300 is configured to operate in environmental pressures in the range of one hundred and one Kilopascals to zero point zero zero one micropascals (101 KPa -0.0001 μPa). In a specific embodiment, the wax actuator 300 is configured to operate in a vacuum in the range of one micropascal to zero point zero one micropascals (1 μPa -0.001 μPa).

In one embodiment, the wax actuator 300 consumes in the range of five to fifty watts (5-50 W). In addition, the wax actuator 300 may operate at between three and forty-eight volts (3-48V). In a certain embodiment, the wax actuator 300 consumes twenty watts (20 W) at twenty-eight volts (28 V).

In one embodiment, the wax actuator 300 may latch the plunger 320 in an extended position. Alternatively, the wax actuator 300 may be configured to latch the plunger 320 in a retracted position. The wax actuator 300 may consume no power with the plunger 320 latched.

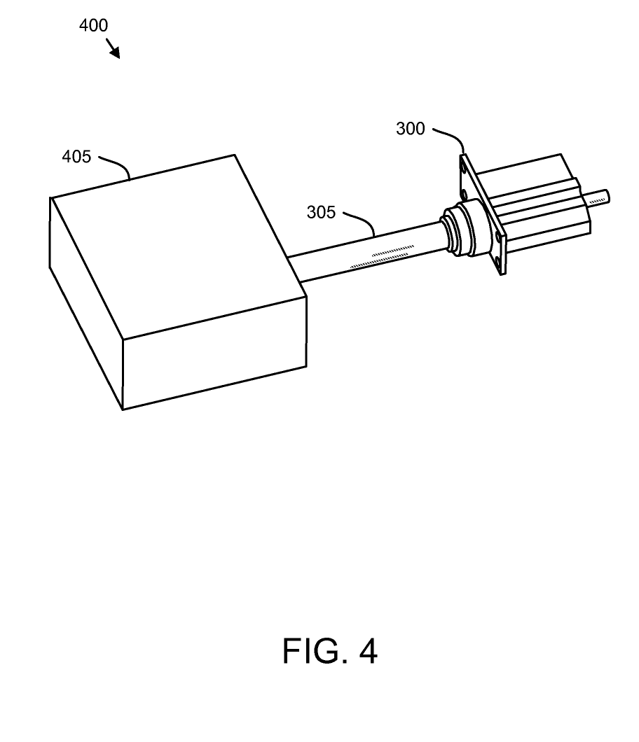

FIG. 4 is a perspective drawing illustrating one embodiment of an actuator control system 400 of the present invention. The description of the system 400 refers to elements of FIGS. 1-3, like numbers referring to like elements. The wax actuator 300 of FIG. 3 is depicted in communication with a controller 405 through the cable 305.

In one embodiment, the controller 405 controls the wax actuator 300, motivating the plunger 320 to extend and retract. In a certain embodiment, the controller 405 switches an electrical current to flow through the wires 330 of the cable to the wax actuator 300. Alternatively, the controller 405 may communicate a signal to the wax actuator 300 and the signal may activate the flow of an electrical current through the wax actuator 300.

In one embodiment, the controller 405 directs the wax actuator 300 to latch the plunger in the extended position and/or in the retracted position. The controller 405 may also direct the wax actuator to unlatch the plunger 320. In an alternate embodiment, the wax actuator 300 may automatically latch the plunger 320 in the extended position when the plunger 320 reaches the extended position. Similarly, the wax actuator 300 may automatically latch the plunger 320 in the retracted position when the plunger 320 reaches the retracted position.

In one embodiment, the wax actuator 300 unlatches the plunger 320 in response to the controller 405 directing the wax actuator 300 to retract the plunger 320. Similarly, the wax actuator 300 may unlatch the plunger 320 in response to the controller 405 directing the wax actuator 300 to extend the plunger 320.

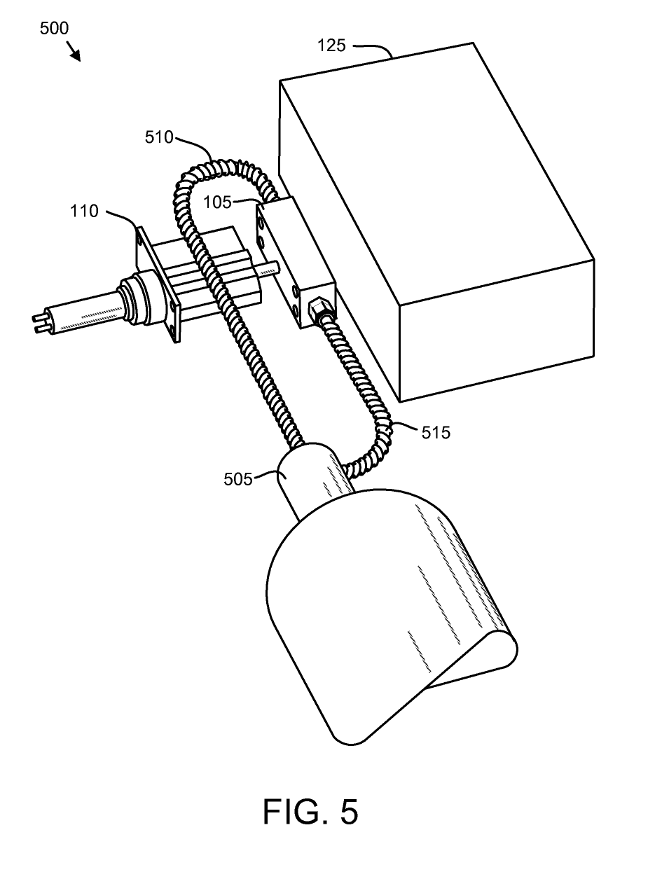

FIG. 5 is a perspective drawing illustrating one embodiment of a cryogen-based thermal transport system 500 of the present invention. The system 500 may embody the apparatus 200 of FIG. 2. In addition, the description of the system 500 refers to elements of FIG. 1, like numbers referring to like elements.

The actuator 110, thermal connector 105, and first body 125 of FIG. 1 are shown with the thermal connector 105 separated from the first body 125. The actuator 110 may be the wax actuator 300 of FIGS. 3 and 4. A cryogen tank 505 contains the cryogen. In one embodiment, the cryogen is liquid nitrogen. The cryogen tank 505 provides cryogen to a delivery line 515. The delivery line 515 delivers the cryogen to the thermal connector 105. The cryogen cools the thermal connector 105. A return line 510 removes cryogen and/or vaporized cryogen from the thermal connector 105.

In one embodiment, the actuator 110 motivates the thermal connector 105 to contact the first body 125. The thermal connector 105 cooled by the cryogen and in contact with the first body 125 may conduct heat from the first body 125 to cool the first body 125. In addition, the actuator 110 may motivate the thermal connector 105 to separate from the first body 125. The separated thermal connector 105 does not conduct heat from the first body 125 and so does not cool the first body.

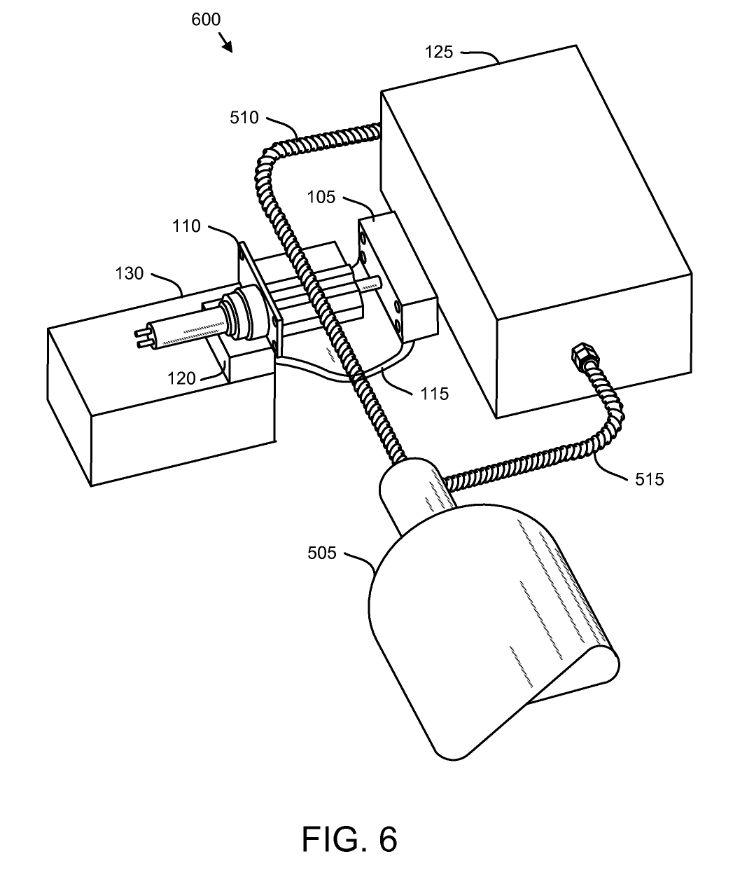

FIG. 6 is a perspective drawing illustrating one alternate embodiment of a cryogen-based thermal transport system 600 of the present invention. The system 600 may embody the apparatus 200 of FIG. 2. In addition, the description of the system 600 refers to elements of FIGS. 1 and 5, like numbers referring to like elements.

The actuator 110, thermal connector 105, first body 125, actuator mount 120, thermal link 115, and second body 130 of FIG. 1 are shown with the thermal connector 105 separated from the first body 125. In addition, the cryogen tank 505, return line 510, and delivery line 515 of FIG. 5 are depicted. The cryogen from the cryogen tank 505 flows thorough the delivery line 515 to the first body 125 where the cryogen cools the first body 125. Used cryogen and/or cryogen vapor flow from the first body 125 through the return line 510.

In one embodiment, the actuator 110 motivates the thermal connector 105 to contact the first body 125. Heat may flow from the second body 130 through the thermal link 115 and the thermal connector 105 to the first body 125, cooling the second body 130. The system 600 supports modifying the thermal connection between the second body heat source and the first body cold sink.

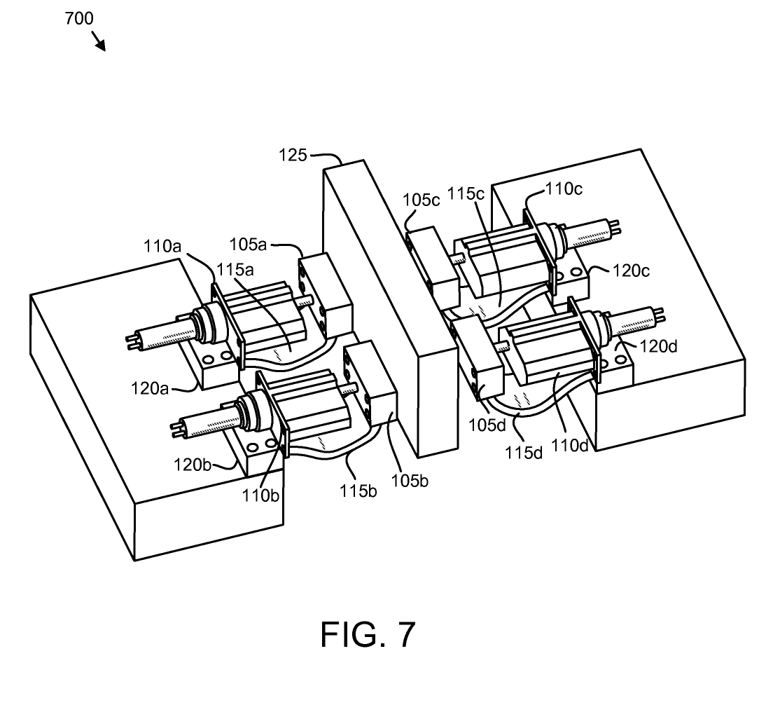

FIG. 7 is a perspective drawing illustrating one embodiment of a zero contact force thermal transport system 700 of the present invention. The description of the system 700 includes elements of FIGS. 1-5, like numbers referring to like elements. The system 700 modifies thermal connections to a first body 125 while preventing a net contact force from being applied to the first body 125.

A plurality of thermal connectors 105 are disposed on opposite sides of the first body 125. Each thermal connector 105 is in thermal communication with a thermal link 115, and each thermal link 115 is in thermal communication with a second body 130a, 130b. In addition, each thermal connector 105 is in physical communication with an actuator 110 and each actuator 110 is mounted through an actuator mount 120 to a second body 130a, 130b.

Each actuator 110 is configured to motivate a thermal connector 105 along a shared axis with an opposing thermal connector 105. As shown, a first thermal connector 105a is configured to be motivated by a first actuator 110a along an axis shared with a third thermal connector 105c motivated by a third actuator 110c. A second thermal connector 105b is also shown configured to be motivated by a second actuator 110a along an axis shared with a fourth thermal connector 105d motivated by a fourth actuator 110d.

In one embodiment, the controller 405 may direct actuators 110 to motivate opposing pairs of thermal connectors 105 to contact the first body 125. In a prophetic example, the controller 405 may direct the first and third actuators 110a, 110c to motivate the first and third thermal connectors 105a, 105c to contact the first body 125 at substantially the same time. In addition, controller 405 may direct the first and third actuators 110a, 110c to motivate the first and third thermal connectors 105a, 105c with substantially equivalent force. Thus the first and third thermal connectors 105a, 105c may together apply a net force of zero newtons (0 N) to the first body 125.

Similarly, the controller 405 may direct the second and fourth actuators 110b, 110d to motivate the second and fourth thermal connectors 105b, 105d to contact the first body 125 at substantially the same time and with substantially the same force. Thus the system 600 may modify the thermal connections to the first body 125 while applying a net zero force to the first body 125.

The schematic flow chart diagrams that follow are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

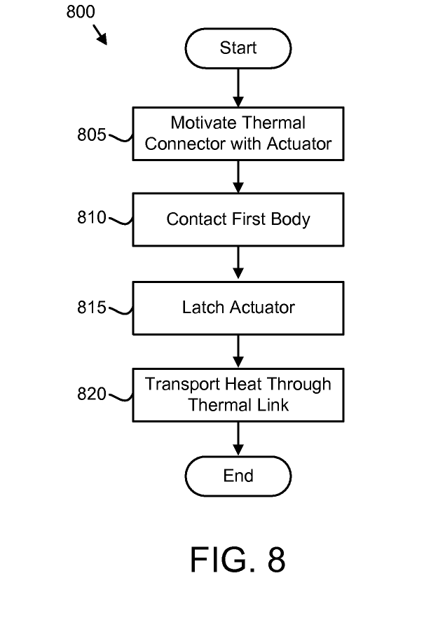

FIG. 8 is a schematic flow chart diagram illustrating one embodiment of a thermal connector contact method of the present invention. The method 800 substantially includes the steps to carry out the functions presented above with respect to the operation of the described apparatus 200, 300 and system 100, 400, 500, 600, 700 of FIGS. 1-7. The description of the method 800 refers to elements of FIGS. 1-7, like numbers referring to like elements.

The method 800 begins and the actuator 110 motivates 805 the thermal connector 105. The actuator 110 may be the wax actuator 300 of FIG. 3 and may motivate the thermal connector 105 in response to melting the thermal expansive substance. The controller 405 may direct the actuator 110 to motivate 805 the thermal connector 105.

In one embodiment, a plurality of actuators 110 motivate a plurality of thermal connectors 105. The controller 405 may specify the number of actuators 110 to motivate in order to transport a specified quantity of heat. In a prophetic example, the controller 405 may need to transfer four hundred joules per minute (400 J/min) of heat from the first body 125. In addition, each thermal connector 105 may be configured to transport two hundred joules per minute (200 J/min) of heat through thermal links 115 to the second body 130. The controller 405 may direct two (2) actuators 110 to motivate two thermal connectors 105 to contact the first body 125 in order to transport the needed quantity of heat.

In an alternate embodiment, the controller 405 may direct each actuator 110 to motivate a corresponding thermal connector 105 in response to feedback one or more sensors disposed on the first body 125. In a prophetic example, the first body 125 may have an operational temperature of minus sixty degrees Celsius (−60° C.). A thermocouple sensor disposed on the first body 125 may report that the temperature of the first body 125 is minus forty degrees Celsius (−40° C.). As a result, the controller 405 may direct the first actuator 110a to motivate the first thermal connector 105a. If the temperature of the first body 125 does not reach minus sixty degrees Celsius (−60° C.), the controller 405 may also direct the second actuator 110b to motivate the second thermal connector 105b to further reduce the temperature of the first body 125.

The thermal connector 105 contacts 810 the first body 125 to form a thermal connection between the thermal connector 105 the first body 125. In one embodiment, the plurality of thermal connectors 105 contact one or more first bodies 125.

In one embodiment, the actuator 110 latches 815 with the thermal connector 105 in contact with the first body 125. The latched actuator 110 may consume no power. In addition, the latched actuator 110 may prevent the thermal connector 105 from separating from the first body 125 and breaking the thermal connection between the first body 125 and the thermal connector 105.

The thermal link 115 transports 820 heat through the thermal connection. In one embodiment, the thermal link 115 transports 820 heat between the first body 125 and the second body 130. Alternatively, the thermal link 115 may comprise a cryogen that cools the thermal connector 105 by transporting 820 heat from the thermal connector 105. The method 800 supports controlling the flow of heat from and/or to the first body 125 controlling the thermal connectors 105 that are motivated 805 to contact 810 the first body 125.

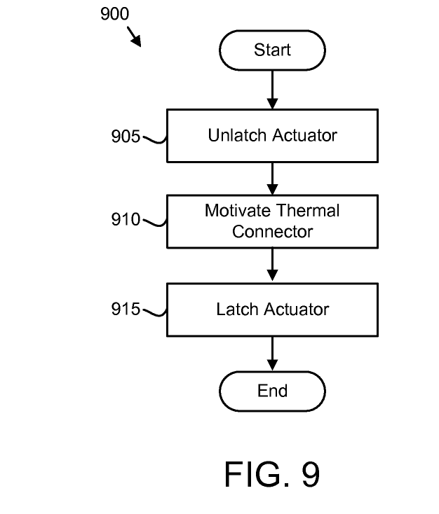

FIG. 9 is a schematic flow chart diagram illustrating one embodiment of a thermal connector separation method 900 of the present invention. The method 900 substantially includes the steps to carry out the functions presented above with respect to the operation of the described apparatus 200, 300 and system 100, 400, 500, 600, 700 of FIGS. 1-7. The description of the method 900 refers to elements of FIGS. 1-8, like numbers referring to like elements.

The method 900 begins and in one embodiment, the actuator 110 unlatches 905 to allow the thermal connector 105 move away from the first body 125. The controller 405 may direct the actuator 110 to unlatch 905.

In one embodiment, the actuator 110 motivates 910 the thermal connector 105 to separate from the first body 125. In an alternate embodiment, a spring motivates the thermal connector 105 to separate from the first body 125. In a certain embodiment, the actuator 110 is the wax actuator 300 and may motivate 910 the thermal connector 105 by melting the thermal expansive substance. The controller 405 may direct the actuator 110 to motivate 910 the thermal connector 105.

In one embodiment, the actuator 110 latches 915 with the thermal connector 105 separated from the first body 125 and the method 900 terminates. The controller 405 may direct the actuator 110 to latch 915. The method 900 separates the thermal connector 105 from the first body 125 to break the thermal connection between the first body 125 and the thermal connector 105, regulating heat transport from and/or to the first body 125.

The embodiment of the present invention modifies a thermal connection. In addition, the embodiment of the present invention may modify the transport of heat to maintain a specified temperature range and/or rate of heat transport. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus to modify a thermal connection, the apparatus comprising:
a first thermal connector configured to contact a first body to form a thermal connection with the first body, the first thermal connector further configured to separate from the first body and break the thermal connection;
a thermal link in thermal communication with the first thermal connector; and
a first actuator configured to motivate the first thermal connector to contact the first body and to motivate the first thermal connector to separate from the first body.

2. The apparatus of claim 1, wherein the first actuator is configured to latch with the first thermal connector in contact with the first body, wherein the latched first actuator consumes no power.

3. The apparatus of claim 2, wherein the first actuator is further configured to latch with the first thermal connector separated from the first body, wherein the latched first actuator consumes no power.

4. The apparatus of claim 1, wherein the first actuator motivates the first thermal connector with a force in the range of 0.4 newtons to 2,500 newtons.

5. The apparatus of claim 1, wherein the first actuator is configured for operation in pressures in the range of 101 KPa to 0.0001 μPa.

6. The apparatus of claim 5, wherein the first actuator is further configured for a vacuum in the range of 1 μPa to 0.001 μPa.

7. The apparatus of claim 1, wherein the first actuator is configured to apply a force in response to heat.

8. The apparatus of claim 7, wherein the first actuator is configured as a wax actuator that motivates the first thermal connector in response to melted wax.

9. The apparatus of claim 1, wherein the first body is a heat load and the thermal link communicates with a second body that is a cold source.

10. The apparatus of claim 1, wherein the first body is a cold load and the thermal link communicates with a second body that is a heat source.

11. The apparatus of claim 1, wherein the thermal link is configured as a flexible member.

12. The apparatus of claim 11, wherein the thermal link is configured as plurality of conductive foil layers.

13. The apparatus of claim 11, wherein the thermal link is configured as a braided conductor.

14. The apparatus of claim 11, wherein the thermal link is configured as a cryogen line.

15. The apparatus of claim 1, wherein the thermal connector and the first body each comprise a contact surface, the thermal connector and first body further configured to contact at the contact surfaces.

16. The apparatus of claim 1, wherein a second actuator motivates a second thermal connector to contact the first body in opposition to the force of the first thermal connector such that there is substantially no net force applied to the first body by the first and second thermal connectors.

17. A system to modify a thermal connection, the system comprising:
a cold source;
a heat load;
a thermal transport comprising
a thermal connector configured to contact the heat load to form a thermal connection with the heat load, the thermal connector further configured to separate from the heat load and break the thermal connection;
a thermal link in thermal communication with the thermal connector and the cold source and configured as a flexible member; and
a wax actuator configured to motivate the thermal connector to contact the heat load, latch with the thermal connector in contact with the first body, unlatch, motivate the thermal connector to separate from the heat load, and latch with the thermal connector separated from the first body, and wherein the latched actuator consumes no power.

18. The system of claim 17, wherein the heat load is disposed on a space vehicle.

19. The system of claim 18, wherein the heat load comprises instrumentation.

20. The system of claim 17, wherein the thermal link is configured as plurality of conductive foil layers.

21. The system of claim 17, wherein the thermal link is configured as a braided conductor and wherein the conductor is selected from copper and aluminum.

22. A method for modifying a thermal connection, the method comprising:
motivating a thermal connector with a wax actuator;
contacting the thermal connector to a first body to form a thermal connection between the thermal connector and the first body; and
conducting heat through a thermal link in thermal communication with the thermal connector.

23. The method of claim 22, the method further comprising latching the wax actuator with the thermal connector in contact with the first body wherein the latched wax actuator consumes no power.

24. The method of claim 23, the method further comprising unlatching the wax actuator and motivating the thermal connector to separate from the first body and break the thermal connection.

25. The method of claim 24, the method further comprising latching the wax actuator with the thermal connector separated from the first body, wherein the latched actuator consumes no power.

26. The method of claim 22, wherein the wax actuator motivates the thermal connector with a force in the range of 0.4 newtons to 2,500 newtons.

27. The method of claim 22, wherein the wax actuator is configured for operation in pressures in the range of 101 KPa to 0.0001 μPa.

28. The method of claim 27, wherein the wax actuator is further configured for a vacuum in the range of 1 μPa to 0.001 μPa.

29. An apparatus to modify thermal connections, the apparatus comprising:
means for motivating a thermal connector wherein the motivating means is configured to provide a force in the range of 0.4 newtons to 2,500 newtons and operate in a vacuum in the range of 1 μPa to 0.001 μPa;
means for contacting a first body to form a thermal connection;
means for latching the motivating means with the contacting means in contact with the first body; and
means for conducting heat through the contacting means;
means for unlatching the motivating means;
means for motivating the contacting means to separate from the first body;
and
means for latching the motivating means with the contacting means separated from the first body.
